(19) United States
(12) Patent Application Publication
(10) Pub. No.: US 2006/0145144 A1
(43) Pub. Date: Jul. 6, 2006

(54) Vertical organic thin film transistor and organic light emitting transistor

(75) Inventors: Sang Yoon Lee, Seoul (KR); Bon Won Koo, Suwon-si (KR); In Nam Kang, Ansan-si (KR); Chang Ju Kim, Anyang-si (KR); Se Young Oh, Seoul (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Samsung Electronics Co., Ltd., Suwon-si (KR)

(21) Appl. No.: 11/229,495

(22) Filed: Sep. 20, 2005

(30) Foreign Application Priority Data
Jan. 5, 2005 (KR) 10-2005-0000848

(51) Int. Cl. H01L 29/08

(52) U.S. Cl. 257/40

(57) ABSTRACT

A vertical organic thin film transistor is provided along with an organic light-emitting transistor, which is characterized in that an active layer is formed of a p-type organic semiconductor compound having a dielectric constant of 3.5 or more, and work function values of an anode and a cathode are different from each other. The vertical organic thin film transistor is advantageous because it exhibits excellent current-voltage properties due to a short channel length, and has simple fabrication processes. Also, in the vertical organic thin film transistor, current properties in response to the gate voltage are of an enhancement type. Therefore, the vertical organic thin film transistor may be fabricated into the organic light-emitting transistor through a simple process.

### BACKGROUND OF THE INVENTION

This non-provisional application claims priority under 35 U.S.C. § 119(a) on Korean Patent Application No. 2005-00848 filed on Jan. 5, 2005, which is herein expressly incorporated by reference.

### 1. FIELD OF THE INVENTION

The embodiments of the present invention relate, generally, to a vertical organic thin film transistor and an organic light-emitting transistor using the same. More particularly, the embodiments of the present invention relate to a vertical organic thin film transistor, in which an active layer is formed of a p-type organic semiconductor compound having a dielectric constant of 3.5 or more, and work function values of an anode electrode and a cathode electrode are different from each other, thus exhibiting high current properties, and to an organic light-emitting transistor using such a vertical organic thin film transistor.

### 2. DESCRIPTION OF THE RELATED ART

Until now, a thin film transistor, which is advantageous because it may be formed on a large-sized substrate, has been practically developed into peripheral devices of liquid crystal displays, laser printer heads, etc., image sensors of scanners, etc., and smart cards. Recently, a thin film transistor has been used for full color operation of an organic EL (electroluminescence) display. Further, since a transistor is fabricated in the form of a thin film, it is employed to manufacture lightweight, conveniently portable products. In particular, each pixel for use in an active display is provided with a thin film transistor. In this way, use of a thin film transistor results in the consumption of less current to emit light through the pixel, very fast on-off operation, and controlled brightness of the pixel depending on the magnitude of the current. Thus, thin film transistors play a leading role in displays requiring higher pixels. Since a thin film transistor applied to a display requires a more rapid response speed, compared to other application fields, it should have a high mobility value and a high on-off current ratio.

Transistors are classified into bipolar transistors and unipolar transistors, based on the operating structure. The bipolar transistor allows current to flow under the influence of both holes and electrons in a semiconductor constituting the transistor, whereas the unipolar transistor allows current to flow under the influence of either holes or electrons.

A field effect transistor (FET), which is mainly applied to electronic devices at present, is a kind of unipolar transistor, and is divided into three types, that is, junction FETs, MOSFETs (Metal-Oxide Semiconductor Field Effect Transistors) and GaAs FETs. Of these FETs, a MOSFET applied to high value electronic products such as displays is advantageous because it can be integrated and has excellent switching properties, but suffers from shortcomings, such as complicated processes of separately fabricating an operating device and a light-emitting device.

Recently, thorough research into polymer materials in fields of functional electronic devices and optical devices has been conducted because the polymer material serving as a new electrical and electronic material is able to be easily formed into a fiber or film, and has flexibility, conductivity, and low production costs. Of devices using a conductive polymer, an organic thin film transistor including a semiconductor active layer made of organic material has been studied since the 1980s, and, these days, is under vigorous study all over the world. This is because an organic thin film transistor may be fabricated by means of a simple technique, such as a printing technique, and thus, it has low fabrication costs, and also, is compatible with flexible substrates.

An organic semiconductor thin film transistor includes a polymer or an oligomer as an active material, unlike conventional amorphous silicon and polysilicon thin film transistors. The efficiency of the organic thin film transistor is controlled by the current density of a minority carrier. This means that improvement to the mobility and energy barrier of the transistor leads to controlled performance of the transistor, as well as controlled operating voltage of the transistor. However, a conventional organic thin film transistor is typically fabricated using unchanged structure and fabrication processes of an inorganic transistor, thus negating advantages such as ultrathinning, fine patterning, and easy processing of the organic material.

A conventional transistor such as a MOSFET is of a horizontal type in which the source and drain electrodes are horizontally disposed and the gate electrode is disposed above or below between the source and drain electrodes. The horizontal transistor has a higher operating voltage and lower efficiency than a vertical transistor, and is unsuitable for use in organic EL devices manufactured through an active matrix process. As for a recently developed vertical organic thin film transistor, thin films of an organic semiconductor compound are vertically interposed between the source electrode and the gate electrode layer and between the gate electrode and the drain electrode, without insulating films. Therefore, the vertical organic thin film transistor exhibits current-voltage properties which are improved by a few tens times or more than conventional horizontal transistors. This means that high efficiency can be obtained at a low voltage. Since the operating voltage is low, a battery having small capacity may be used for a long time. Hence, the vertical organic thin film transistor is expected to greatly contribute to the manufacture of portable displays. Further, in the vertical organic thin film transistor, the channel length, i.e., the distance between the source electrode and the drain electrode, is short, and thus, high-speed switching is achieved. Therefore, the vertical transistor is believed to provide new opportunities for miniaturization and high performance of a conventional semiconductor technique. However, the current-voltage properties of the vertical organic thin film transistor are of a depletion type in which the source-drain current decreases in inverse proportion to an increase in the gate voltage. Accordingly, a light-emitting transistor manufactured using the vertical organic transistor is disadvantageous because it has low light-emitting efficiency.

### OBJECTS AND SUMMARY

Accordingly, the embodiments of the present invention have been made keeping in mind the above problems occurring in the related art, and an object of the embodiments of the present invention is to provide a vertical organic thin film transistor, in which current-voltage properties of the organic thin film transistor are of an enhancement type, increasing in proportion to an increase in the gate voltage.

Another object of the embodiments of the present invention is to provide an integrated organic light-emitting transistor, which is formed by forming a light-emitting organic layer having light-emitting properties on the enhancement type organic thin film transistor, thus exhibiting high light-emitting efficiency.

In order to accomplish the above objects, according to an embodiment of the present invention, a vertical organic thin film transistor is provided, in which an active layer is formed of a p-type active organic semiconductor compound having a dielectric constant of 3.5 or more, and a source electrode is formed of a material having a work function value different from that of a material of a drain electrode.

According to another embodiment of the present invention, a vertical organic light-emitting transistor is provided, which comprises a substrate, a source electrode, a first p-type organic semiconductor layer, a gate electrode, a second p-type organic semiconductor layer, a light-emitting organic layer, and a drain electrode, which are sequentially stacked, in which the first and second p-type organic semiconductor layers are formed of a p-type active organic semiconductor compound having a dielectric constant of 3.5 or more, and the source electrode is formed of a material having a work function value different from that of a material of the drain electrode.

### BRIEF DESCRIPTION OF THE DRAWINGS

The above and other objects, features and advantages of the embodiments of the present invention will be more clearly understood from the following detailed description taken in conjunction with the accompanying drawings, in which:

FIG. 1 is a schematic sectional view showing a vertical organic thin film transistor according to an embodiment of the present invention;

FIG. 2 is a top plan view showing a vertical organic thin film transistor array according to an embodiment of the present invention;

FIG. 3 is a schematic view showing the structure of a mask used to form a fine pattern of gate electrodes of the embodiments of the present invention;

FIG. 4 is a schematic sectional view showing an organic light-emitting transistor according to another embodiment of the present invention;

FIGS. 5a and 5b are graphs showing the current-voltage properties of the vertical organic thin film transistor fabricated in Example 1;

FIGS. 6a and 6b are graphs showing the current-voltage properties of the vertical organic thin film transistor fabricated in Example 2;

FIGS. 7a and 7b are graphs showing the current-voltage properties of the vertical organic thin film transistor fabricated in Comparative Example 1;

FIGS. 8a and 8b are graphs showing the current-voltage properties of the vertical organic thin film transistor fabricated in Comparative Example 2; and

FIGS. 9a and 9b are graphs showing the current-voltage properties of the organic light-emitting transistor fabricated in Example 12.

### DETAILED DESCRIPTION OF THE PREFERRED THE EMBODIMENTS

Hereinafter, a detailed description will be given of vertical organic thin film transistors and organic light-emitting transistors of the embodiments of the present invention, with reference to the appended drawings.

A vertical organic thin film transistor of the embodiments of the present invention is characterized in that an active layer constituting the transistor may be formed of a p-type organic semiconductor compound having a dielectric constant of 3.5 or more, and a source electrode may be formed of a material having a work function value different from that of a material of a drain electrode.

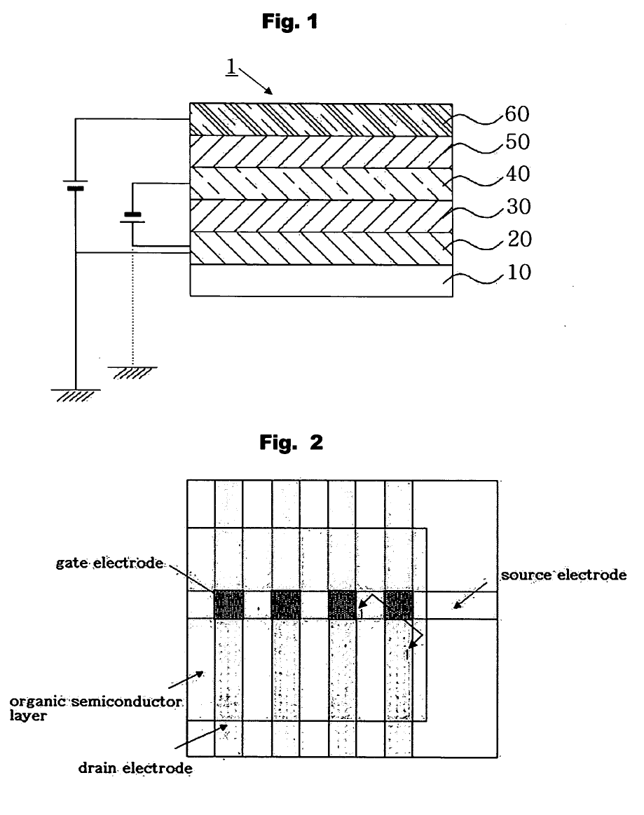

FIG. 1 is a schematic sectional view showing a vertical organic thin film transistor according to an embodiment of the present invention, and FIG. 2 is a top plan view showing a vertical organic thin film transistor array according to an embodiment of the present invention. Specifically, FIG. 2 shows a vertical organic thin film transistor array formed from a common source electrode and multiple drain electrodes in combination with gate electrodes arranged in a grid shape.

As shown in FIGS. 1 and 2, a vertical organic thin film transistor 1 of an embodiment of the present invention includes a substrate 10, a source electrode 20, a first p-type organic semiconductor layer 30, a gate electrode 40, a second p-type organic semiconductor layer 50, and a drain electrode 60, sequentially stacked. The first p-type organic semiconductor layer 30 and the second p-type organic semiconductor layer 50 are formed of a p-type active organic semiconductor compound having a dielectric constant of 3.5 or more. The source electrode 20, serving as the anode with the gate electrode 40, is formed of a material having a work function value different from that of a material of the drain electrode 60 serving as the cathode.

In the embodiments of the present invention, the p-type organic semiconductor compound having a dielectric constant of 3.5 or more is preferably a metal phthalocyanine based compound represented by Formula 1, below:

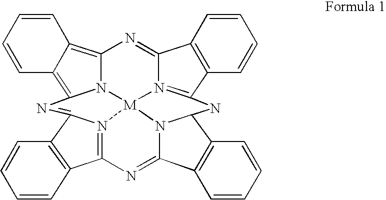

Wherein M is a metal atom selected from the group consisting of Cu, Ni, Zn, Fe and Co.

The preferable materials for p-type organic semiconductor layers 30 and 50 in the embodiments of the present invention are a copper phthalocyanine compound or a nickel phthalocyanine compound, among compounds represented by Formula 1.

Further, the source electrode 20, the gate electrode 40 and the drain electrode 60 are preferably formed of a material selected from the group consisting of gold, silver, chromium, tantalum, titanium, copper, aluminum, molybdenum, tungsten, nickel, palladium, platinum, tin, oxides thereof, ITO (indium tin oxide), and conductive polymers. The conductive polymer includes, for example, poly(anilines), poly(pyrroles), or poly(thiazyls), but is not limited thereto.

In embodiments of the present invention, an anode electrode (source electrode and gate electrode) and a cathode electrode (drain electrode) are formed of materials having work function values different from each other. Preferably, the source electrode is formed of ITO, while the drain electrode is preferably formed of aluminum.

The substrate 10 is preferably formed of glass, silicon, crystal, polyethylenenaphthalate (PEN), polyethyleneterephthalate (PET), polycarbonate, polyvinylalcohol, polyacrylate, polyimide, polynorbornene, or polyethersulfone (PES), but is not limited thereto.

In the embodiments of the present invention, in order to fabricate an enhancement type organic thin film transistor, a p-type organic semiconductor compound having a dielectric constant of 3.5 or more is preferably used. For example, a metal phthalocyanine based organic material that has a dielectric constant (ε=3.6) higher than a dielectric constant of a general organic semiconductor active material and that also has a HOMO (Highest Occupied Molecular Orbit) level of 5.2 eV causes easy hole injection from a source electrode, preferably of ITO (energy level=4.8 eV). In addition, a metal phthalocyanine based material has a hole mobility of 1×10⁻⁵ cm²/V⁻¹s⁻¹, which is lower than almost all of the p-type organic active materials.

Generally, when a voltage is applied to a gate electrode of a vertical organic thin film transistor, a potential barrier is formed on the surface of the organic semiconductor active material that is in contact with the gate electrode, which impedes hole or electron movement. The current-voltage properties of source-drain electrodes are of a depletion type in which current decreases in inverse proportion to an increase in the gate voltage.

In contrast, in the embodiments of the present invention, a vertical organic thin film transistor using a p-type organic semiconductor compound having a dielectric constant of 3.5 or more has a current of the source-drain electrodes that increases in proportion to an increase in the gate voltage. Although a physical mechanism for the enhancement type current-voltage properties of a vertical organic thin film transistor of the embodiments of the present invention is not accurately known, it seems to be caused by the following physical factors. First, since the p-type organic semiconductor compound has a very large dielectric constant of 3.5 or more, when a positive (+) electrical field is applied to the gate electrode, negative (−) charges, acting as a minority carrier in the semiconductor active material, are electrically charged at the interface between the gate electrode and the semiconductor active layer. As such, the minority carriers are moved toward the source electrode by the positive (+) electrical field of the source electrode and, thus, trapped. Due to the minority carriers thus trapped, hole injection from the source electrode to the organic semiconductor compound having a dialectic constant of 3.5 or more increasingly occurs and, thus, the current properties are of an enhancement type. Since the mobility of the organic semiconductor compound having a dialectic constant of 3.5 or more is low, the current of source-drain has a low value when the voltage is not applied to the gate. When a positive (+) electrical field is applied to the gate electrode, new hole injection is induced from the gate electrode. In the system showing relatively low current properties, the new carrier injection is believed to act as an important physical factor for the enhancement of current properties. In addition, complicated physical phenomena, such as the potential difference between the source electrode and the drain electrode, appear to affect the exhibition of the enhancement type current-voltage properties of the vertical organic transistor of the embodiments of the present invention. That is, physical factors such as dielectric constants, mobility and HOMO levels of the organic semiconductor compound, play an important role in the fabrication of the enhancement type vertical organic transistor. Thus, the active layer of the vertical organic thin film transistor of the embodiments of the present invention is preferably formed of a p-type organic semiconductor material having a dielectric constant of 3.5 or more.

The vertical organic thin film transistor shown in FIG. 1 is operated by applying a positive (+) electrical field to the source electrode 20 (e.g., preferably an ITO source electrode), applying a positive (+) electrical field to the gate electrode 40, and applying a negative (−) electrical field to the drain electrode 60 (e.g., preferably an Al drain electrode). Preferably, ITO is used for the source electrode 20 that has a low work function (Φ) of 4.8 eV to allow holes to be easily injected into the organic active layer. Preferably, Al is used for the drain electrode 60 that has a high work function (Φ) of 4.2 eV to allow electrons to be easily injected into the organic active layer.

A method, according to an embodiment of the present invention, of fabricating a vertical organic thin film transistor array, as shown in FIG. 2, is as follows. ITO is used for a source electrode and aluminum (Al) serves as a gate electrode and a drain electrode. The source electrode 20 is patterned using a chemical process on a substrate 10, and a p-type active organic semiconductor compound having a dielectric constant of 3.5 or more is deposited on the patterned ITO source electrode to form a first p-type organic semiconductor layer 30.

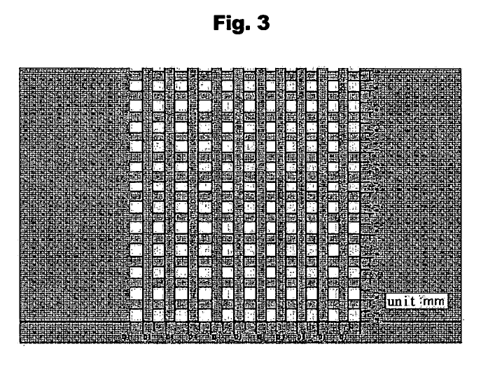

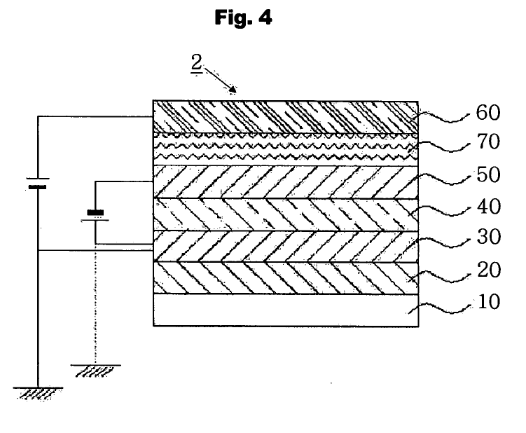

Subsequently, on the first p-type organic semiconductor layer 30, gate electrodes 40 arranged in a grid shape are formed to a predetermined thickness using a metal mask for the formation of a fine electrode pattern as shown in FIG. 3. FIG. 3 shows a metal mask having a line width of about 100 μm, as seen from the axis labels of 0.1 mm. Then, a second p-type organic semiconductor layer 50 is formed on the gate electrodes 40 in the same manner as the first p-type organic semiconductor layer 30. Finally, drain electrodes 60 are formed on the second p-type organic semiconductor layer 50.

In the embodiments of the present invention, the electrodes 20, 40, and 60 and organic semiconductor layers 30 and 50 may be formed by use of a solution process, such as dip coating, spin coating, printing, spray coating, roll coating, etc., a vacuum evaporation process, a chemical vapor deposition process, a printing process, a molecular beam epitaxy process, or suitable processes known to one skilled in the art.

In addition, according to an embodiment of the present invention, an integrated organic light-emitting transistor having high efficiency is provided, which may be formed by forming a light-emitting organic layer having light-emitting properties on the second organic semiconductor layer of the vertical organic thin film transistor. Since a vertical organic transistor of the embodiments of the present invention manifests enhancement type current-voltage properties and excellent switching properties, the light-emitting organic layer may be formed as part of a vertical organic thin film transistor, thereby more simply fabricating the integrated organic light-emitting transistor. In particular, the current-voltage properties of the vertical organic transistor are of the enhancement type, and thus, the light-emitting efficiency of the light-emitting device is improved.

FIG. 4 is a schematic sectional view showing an organic light-emitting transistor 2 according to an embodiment of the present invention. As shown in FIG. 4, an organic light-emitting transistor of the embodiments of the present invention includes a light-emitting organic layer 70 interposed between the second p-type organic semiconductor layer 50 and the drain electrode 60 of a vertical organic thin film transistor according to an embodiment of the present invention, and therefore, has a structure composed of a substrate 10, a source electrode 20, a first p-type organic semiconductor layer 30, a gate electrode 40, a second p-type organic semiconductor layer, a light-emitting organic layer 70 and a drain electrode 60, sequentially stacked. The organic light-emitting transistor 2 is characterized in that the first and second p-type organic semiconductor layers 30 and 50 are formed of a p-type active organic semiconductor compound having a dielectric constant of 3.5 or more, and the source electrode 20, serving as the anode with the gate electrode 40, is formed of a material having a work function value different from that of a material of the drain electrode 60 serving as the cathode.

The light-emitting organic layer 70 is preferably formed of a material selected from the group consisting of spiro-TAD, spiro-NPB, mMTDATA, spiro-DPVBi, DPVBi, Alq, Alq₃ (aluminum tris(8-hydroxyquinoline)), Almg₃, and derivatives thereof. The light-emitting organic layer 70 is preferably 600-1000 Å thick.

A vertical organic thin film transistor of the embodiments of the present invention may be used to manufacture displays, such as liquid crystal displays, electrophoretic devices, organic EL devices, etc.

A better understanding of the embodiments of the present invention may be obtained in light of the following examples which are set forth to illustrate, but are not to be construed to limit the embodiments of the present invention.

### EXAMPLE 1

Fabrication of Vertical Organic Thin Film Transistor Using Copper Phthalocyanine (Cupc)

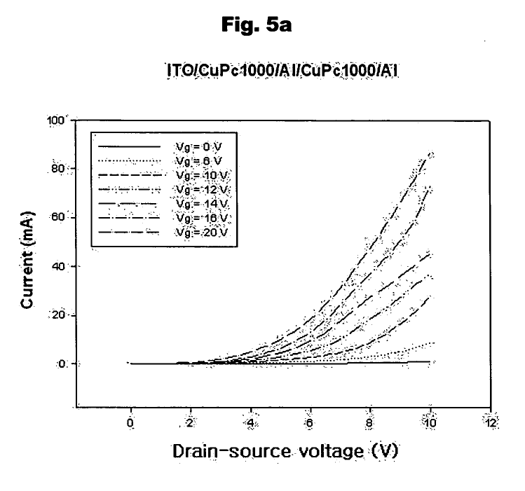

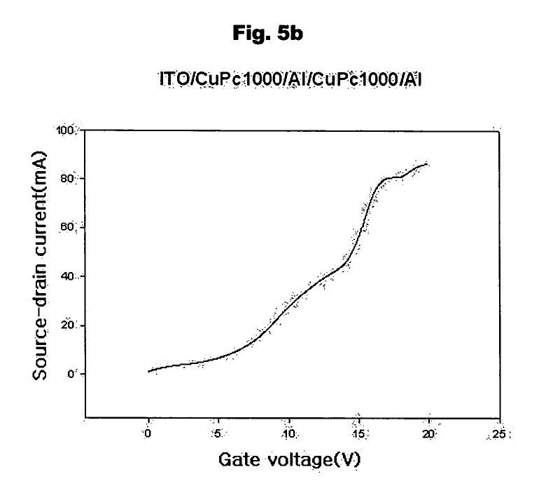

On a glass substrate coated with ITO, a pattern having a desired shape was formed using a chemical resistant tape. The patterned ITO substrate was dipped into an aqueous solution of hydrochloric acid, after which an unnecessary ITO portion was removed using magnesium powder to obtain the substrate on which only a desired pattern remained, which was then washed with an acetone solvent and dried, thus forming an ITO pattern of a source electrode. On the patterned ITO electrode, copper phthalocyanine was deposited to a thickness of 1000 Å under about 10⁻⁵ torr using a vacuum evaporator, to form a first p-type organic semiconductor layer. Subsequently, gate electrodes arranged in a grid shape were deposited to a thickness of 100 Å using a metal mask, as shown in FIG. 3, having a line width of about 100 μm, on the first p-type organic semiconductor layer. Thereafter, a 1000 Å thick second p-type organic semiconductor layer was formed a gate electrode using copper phthalocyanine in the same manner as the first organic semiconductor layer. Finally, as a drain electrode, aluminum was vacuum deposited to a thickness of 1000 Å on the second organic semiconductor layer, thereby fabricating a vertical organic thin film transistor. The current-voltage properties of the vertical organic thin film transistor thus obtained were measured. The results are shown in FIGS. 5a and 5b. FIG. 5a shows results at multiple gate voltages, Vg, specifically, at gate voltages of 0, 6, 10, 12, 14, 16, and 20 V.

### EXAMPLE 2

Fabrication of Vertical Organic Thin Film Transistor Using Nickel Phthalocyanine (NiPc)

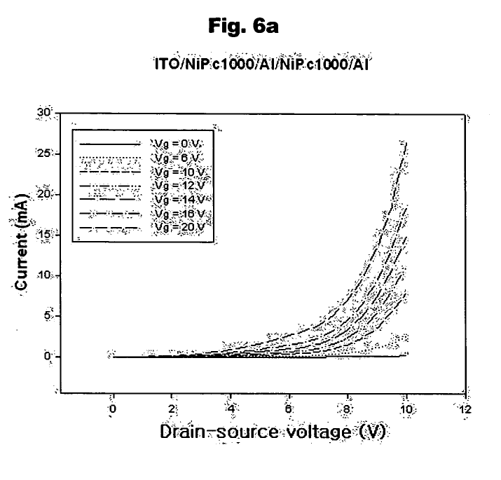

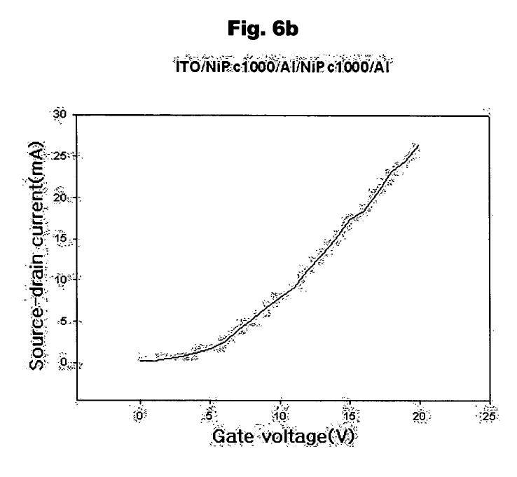

Chemically patterned ITO, 1000 Å thick nickel phthalocyanine, a 100 Å aluminum electrode, 1000 Å thick nickel phthalocyanine, and a 1000 Å thick aluminum electrode, in that order, were vertically deposited in a vacuum (1×10⁻⁶ torr), thus fabricating a vertical organic thin film transistor. The current-voltage properties of the vertical organic thin film transistor thus obtained were measured. The results are shown in FIGS. 6a and 6b. FIG. 6a shows results at multiple gate voltages, Vg, specifically, at gate voltages of 0, 6, 10, 12, 14, 16, and 20 V.

### EXAMPLES 37

Respective vertical organic thin film transistors were fabricated in the same manner as in Example 1, with the exception that the structure of the gate electrodes were varied as shown in Table 1, below. The current-voltage properties of the vertical organic thin film transistor thus obtained were measured. The results are shown in Table 1, below.

TABLE 1

| Ex. No. | Gate Structure | Vds (V) | Current (A) | On/Off Ratio |
|---|---|---|---|---|
| 3 | Line 0.1 mm, Area: 1 mm² | 10 | Vg = 0V: 0.253 × 10⁻³ A | 95.78 |
| | | | Vg = 20V: 24.20 × 10⁻³ A | |
| 4 | Zipper type, Area: 1 mm² | 10 | Vg = 0V: 0.107 × 10⁻³ A | 86.1 |
| | | | Vg = 20V: 9.21 × 10⁻³ A | |
| 5 | Line 0.1 mm, Area: 4 mm² | 10 | Vg = 0V: 1.11 × 10⁻³ A | 78 |
| | | | Vg = 20V: 86.80 × 10⁻³ A | |
| 6 | Line 0.3 mm, Area: 4 mm² | 10 | Vg = 0V: 0.492 × 10⁻³ A | 60 |
| | | | Vg = 20V: 29.50 × 10⁻³ A | |
| 7 | Grid, Area: 4 mm² | 10 | Vg = 0V: 0.374 × 10⁻³ A | 112 |
| | | | Vg = 20V: 41.438 × 10⁻³ A | |

### EXAMPLES 8-11

Respective vertical organic thin film transistors were fabricated in the same manner as in Example 1, with the exception that the gate structure was not patterned, and the thickness of each organic semiconductor layer was varied as shown in Table 2, below. The current-voltage properties of a vertical organic thin film transistor thus obtained was measured. The results are shown in Table 2, below. As such, the channel area was 9 mm², and the gate voltage (Vg) was varied from 0 to 8 V.

TABLE 2

| Ex. No. | Organic Active Layer (Å) | Vds (V) | Current A | On/Off Ratio |
|---|---|---|---|---|
| 8 | 1000 | 10 | Vg = 0V: 5.19 × 10⁻² A | 1.6 |
| | | | Vg = 8V: 8.33 × 10⁻² A | |
| 9 | 2000 | 10 | Vg = 0V: 1.49 × 10⁻³ A | 9.36 |
| | | | Vg = 8V: 1.39 × 10⁻² A | |
| 10 | 3000 | 10 | Vg = 0V: 3.14 × 10⁻⁵ A | 4.33 |
| | | | Vg = 8V: 1.36 × 10⁻⁴ A | |
| 11 | 4000 | 10 | Vg = 0V: 9.02 × 10⁻⁵ A | 1.26 |
| | | | Vg = 8V: 1.14 × 10⁻⁴ A | |

From the results of Tables 1 and 2, it can be seen that when the thickness of each organic active layer of the vertical organic thin film transistor is 1000 Å and gate electrodes arranged in a grid shape are formed with a mask having a line width of 100 μm, the current-voltage properties are optimally manifested and the on-off ratio is the highest.

### COMPARATIVE EXAMPLE 1

Fabrication of Vertical Organic Thin Film Transistor Using Pentacene

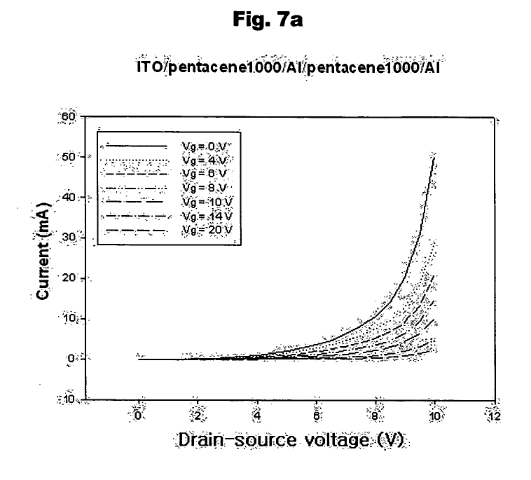

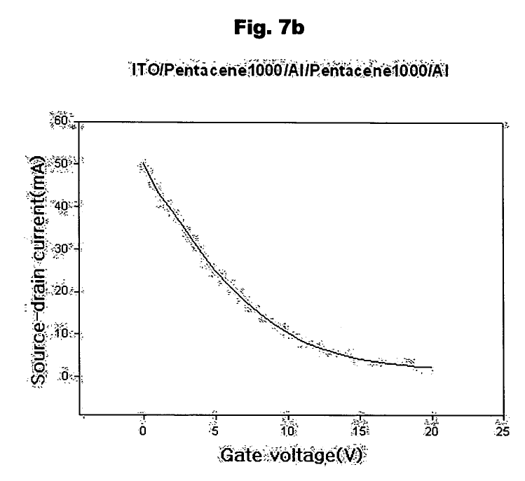

Chemically patterned ITO, 1000 Å thick pentacene, a 100 Å aluminum electrode, 1000 Å thick pentacene, and a 1000 Å thick aluminum electrode, in that order, were vertically deposited in a vacuum (1×10⁻⁶ torr), thus fabricating a vertical organic thin film transistor. The current-voltage properties of the vertical organic thin film transistor thus obtained were measured. The results are shown in FIGS. 7a and 7b. FIG. 7a shows results at multiple gate voltages, Vg, specifically, at gate voltages of 0, 4, 6, 8, 10, 14, and 20 V.

As shown in FIGS. 7a and 7b, the vertical organic thin film transistor fabricated using a different kind of p-type organic active material (pentacene) having a dielectric constant less than 3 exhibits depletion type current-voltage properties.

### COMPARATIVE EXAMPLE 2

Fabrication of Vertical Organic Thin Film Transistor of Copper Phthalocyanine (CuPc) Using Only Al Metal Electrode

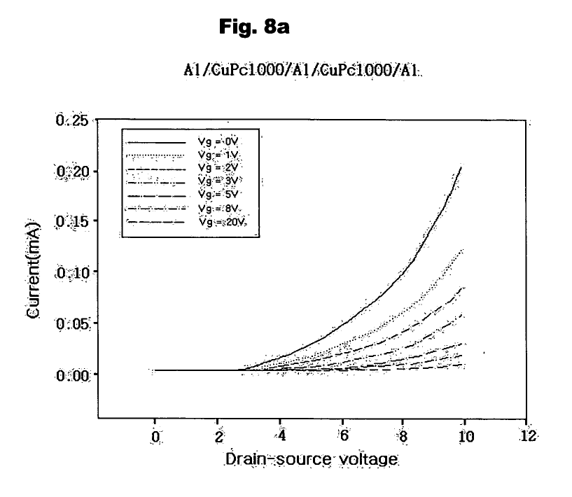

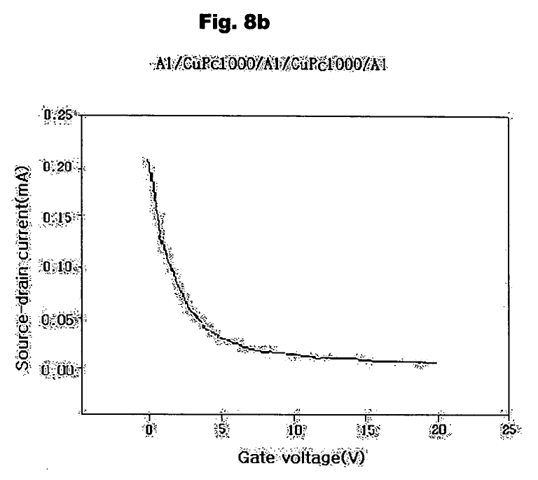

Aluminum deposited to a thickness of 1000 Å using a mask, 1000 Å thick copper phthalocyanine, a 100 Å aluminum electrode, 1000 Å thick copper phthalocyanine, and a 1000 Å thick aluminum electrode, in that order, were vertically deposited in a vacuum (1×10⁻⁶ torr), thus fabricating a vertical organic thin film transistor. The current-voltage properties of the vertical organic thin film transistor thus obtained were measured. The results are shown in FIGS. 8a and 8b. FIG. 7a shows results at multiple gate voltages, Vg, specifically, at gate voltages of 0, 1, 2, 3, 5, 8, and 20 V. As is apparent from FIGS. 8a and 8b, if the cathode (drain electrode) and anode (source electrode and gate electrode) are formed of a material having the same work function value, enhancement type current-voltage properties cannot be obtained.

### EXAMPLE 12

Fabrication of Organic Light-Emitting Transistor

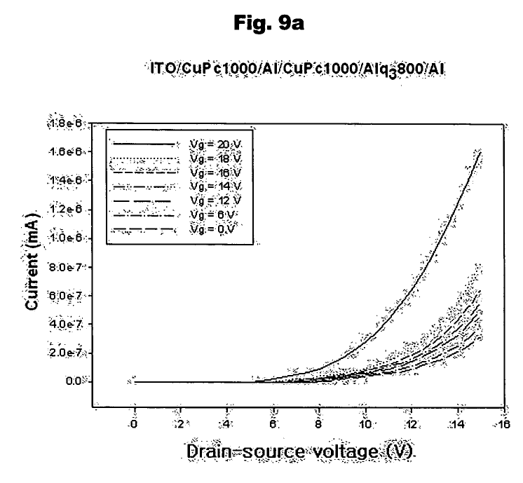

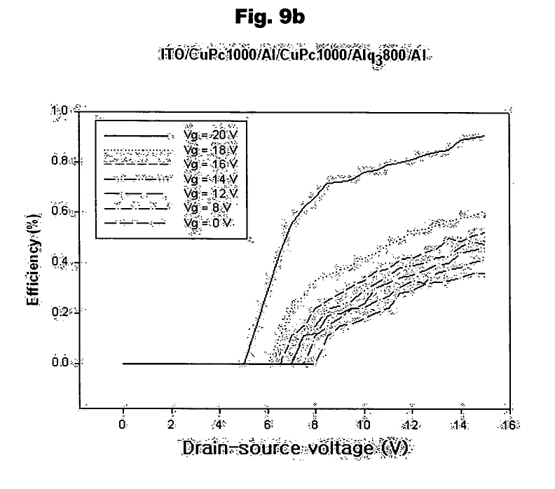

Chemically patterned ITO, 1000 Å thick copper phthalocyanine, a 100 Å aluminum electrode, 1000 Å thick copper phthalocyanine, an 800 Å thick Alq₃ light-emitting organic layer, and a 1000 Å thick aluminum electrode, in that order, were vertically deposited in a vacuum (1×10⁻⁶ torr), thus fabricating a vertical organic light-emitting transistor. The current-voltage properties of the vertical organic light-emitting transistor thus obtained were measured. The results are shown in FIGS. 9a and 9b. FIG. 9a shows results at multiple gate voltages, Vg, specifically, at gate voltages of 20, 18, 16, 14, 12, 6 and 0 V. FIG. 9b shows results at multiple gate voltages, Vg, specifically, at gate voltages of 20, 18, 16, 14, 12, 8 and 0 V. As in FIGS. 9a and 9b, on-off operation of the light-emitting device is made possible by the vertical organic transistor. In particular, very high light-emitting efficiency (0.91%) is manifested at 20 V, due to the enhancement type current-voltage properties of the vertical organic transistor.

As described hereinbefore, the embodiments of the present invention provide a vertical organic thin film transistor and an organic light-emitting transistor. A vertical organic thin film transistor of the embodiments of the present invention may have a high operation speed due to a short channel length and may be fabricated at low cost using a simple process, such as spin coating. In addition, current-voltage properties are of an enhancement type in which the source-drain current value increases in proportion to an increase in the gate voltage, and excellent switching properties may be manifested. Thus, the vertical organic thin film transistor of the embodiments of the present invention may be suitable for application to operating devices of flat panel displays. Further, the vertical organic thin film transistor is advantageous because it may have superb switching properties and may be used at a low frequency, and hence, it is applicable to small electronic devices, and as well, various future electronic devices, such as e-paper, e-books, smart cards, etc. Moreover, due to the above properties of the vertical organic thin film transistor of the embodiments of the present invention, an integrated organic light-emitting transistor having a high light-emitting efficiency may be more simply fabricated by forming a light-emitting organic layer on the vertical organic thin film transistor.

Although preferred the embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A vertical organic thin film transistor comprising at least two active layers, a source electrode and a drain electrode, wherein each active layer, independently, comprises a p-type active organic semiconductor compound having a dielectric constant of 3.5 or more, and the source electrode comprises a material having a work function value different from that of a material of the drain electrode.

2. The thin film transistor as set forth in claim 1, wherein the vertical organic thin film transistor has a structure comprising a substrate, a source electrode, a layer of p-type active organic semiconductor compound having a dielectric constant of 3.5 or more a gate electrode, a second layer of p-type active organic semiconductor compound having a dielectric constant of 3.5 or more, and a drain electrode, which are sequentially stacked.

3. The thin film transistor as set forth in claim 2, wherein the p-type organic semiconductor compound having a dielectric constant of 3.5 or more is a metal phthalocyanine based compound represented by Formula 1, below: 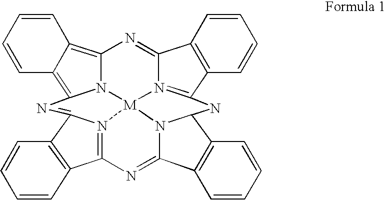
wherein M is a metal selected from the group consisting of Cu, Ni, Zn, Fe, and Co.

4. The thin film transistor as set forth in claim 1, wherein each active layer is 800-1200 Å thick.

5. The thin film transistor as set forth in claim 1, wherein the source electrode and the drain electrode, independently, comprise a material selected from the group consisting of gold, silver, chromium, tantalum, titanium, copper, aluminum, molybdenum, tungsten, nickel, palladium, platinum, tin, oxides thereof, indium tin oxide (ITO), and conductive polymers.

6. The thin film transistor as set forth in claim 5, wherein the conductive polymer is selected from the group consisting of poly(anilines), poly(pyrroles), and poly(thiazyls).

7. The thin film transistor as set forth in claim 1, wherein the source electrode is an ITO electrode and the drain electrode is an aluminum electrode.

8. The thin film transistor as set forth in claim 2, wherein the source electrode is an ITO electrode and the drain electrode is an aluminum electrode.

9. The thin film transistor as set forth in claim 2, wherein the gate electrode was formed from a grid shape.

10. The thin film transistor as set forth in claim 9, wherein the grid shape is a metal mask having a line width of about 100 μm.

11. The thin film transistor as set forth in claim 2, wherein the substrate comprises a material selected from the group consisting of glass, silicon, crystal, polyethylenenaphthalate, polyethyleneterephthalate, polycarbonate, polyvinylalcohol, polyacrylate, polyimide, polynorbornene, and polyethersulfone.

12. The thin film transistor as set forth in claim 2, wherein each organic semiconductor layer is 1000 Å thick.

13. The thin film transistor as set forth in claim 2, wherein each electrode and each organic semiconductor layer is formed by a process selected from the group consisting of a solution process, a vacuum evaporation process, a chemical vapor deposition process, a printing process, and a molecular beam epitaxy process.

14. A vertical organic light-emitting transistor, comprising a substrate, a source electrode, a first p-type organic semiconductor layer, a gate electrode, a second p-type organic semiconductor layer, a light-emitting organic layer, and a drain electrode, which are sequentially stacked, in which the first and second p-type organic semiconductor layers comprise a p-type active organic semiconductor compound having a dielectric constant of 3.5 or more, and the source electrode comprises a material having a work function value different from that of a material of the drain electrode.

15. The light-emitting transistor as set forth in claim 14, wherein the p-type organic semiconductor compound having a dielectric constant of 3.5 or more is a metal phthalocyanine based compound represented by Formula 1, below: 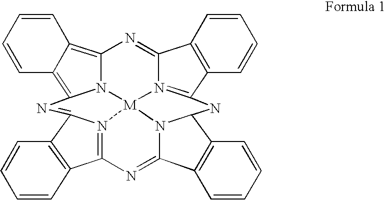
wherein M is a metal atom selected from the group consisting of Cu, Ni, Zn, Fe, and Co.

16. The light-emitting transistor as set forth in claim 14, wherein each organic semiconductor layer is 1000 Å thick.

17. The light-emitting transistor as set forth in claim 14, wherein the light-emitting organic layer comprises a material selected from the group consisting of spiro-TAD, spiro-NPB, mMTDATA, spiro-DPVBi, DPVBi, Alq, Alq₃ (aluminum tris(8 hydroxyquinoline)), Almg₃, and derivatives thereof.

18. The light-emitting transistor as set forth in claim 14, wherein the gate electrode, the source electrode, and the drain electrode, independently, comprise a material selected from the group consisting of gold, silver, chromium, tantalum, titanium, copper, aluminum, molybdenum, tungsten, nickel, palladium, platinum, tin, oxides thereof, ITO, and conductive polymers.

19. The light-emitting transistor as set forth in claim 18, wherein the conductive polymer is selected from the group consisting of poly(anilines), poly(pyrroles), and poly(thiazyls).

20. The light-emitting transistor as set forth in claim 14, wherein the source electrode is an ITO electrode and the drain electrode is an aluminum electrode.

21. The light-emitting transistor as set forth in claim 14, wherein the gate electrode was formed from a grid shape.

22. The light-emitting transistor as set forth in claim 21, wherein the grid shape is a metal mask having a line width of about 100 μm.

23. The light-emitting transistor as set forth in claim 14, wherein the substrate comprises a material selected from the group consisting of glass, silicon, crystal, polyethylenenaphthalate, polyethyleneterephthalate, polycarbonate, polyvinylalcohol, polyacrylate, polyimide, polynorbornene, and polyethersulfone.

24. The light-emitting transistor as set forth in claim 14, wherein each electrode and each organic semiconductor layer is formed by a process selected from the group consisting of a solution process, a vacuum evaporation process, a chemical vapor deposition process, a printing process, and a molecular beam epitaxy process.

25. The light-emitting transistor as set forth in claim 14, wherein light-emitting organic layer is 600 to 1000 Å thick.

26. A display manufactured using the organic thin film transistor of claim 1.

27. A display manufactured using the organic thin film transistor of claim 2.

28. A display manufactured using the organic light-emitting transistor of claim 14.
